(19) United States
(12) Patent Application Publication
(10) Pub. No.: US 2007/0017696 A1
(43) Pub. Date: Jan. 25, 2007

(54) Multi-layer printed circuit board

(75) Inventors: Yu-Hsu Lin, San Jose, CA (US); Shang-Tsang Yeh, Tu-Cheng (TW); Chao-Chen Huang, Tu-Cheng (TW); Chuan-Bing Li, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/488,490

(22) Filed: Jul. 18, 2006

(30) Foreign Application Priority Data
Jul. 22, 2005 (CN) 200510036143.9

(51) Int. Cl. H05K 1/11

(52) U.S. Cl. 174/255; 174/262

(57) ABSTRACT

A multi-layer printed circuit board (PCB) is provided allowing balanced power supply to components requiring large working current. The PCB includes a plurality of layers disposed thereon. A first power area, and a second power area are separately arranged on different layers. The first power area and the second power area vertically aligned within the PCB with generally identical shapes cooperatively provide power to components requiring large working current.

### BACKGROUND

1. Field of the Invention

The present invention relates to multi-layer printed circuit boards (PCBs), and more particularly to a multi-layer PCB which is capable of providing a balanced power supply to a component requiring large working current and efficiently maintaining PCB integrity.

2. General Background

Conventionally, components requiring large working currents (such as central processing units (CPUs), Voltage Regulator Modules (VRMs), North Bridge Chips (NBCs), and memories mounted on PCBs often require dual power areas provided by a power supply. The dual power areas with identical voltages are typically disposed in two different layers (such as a power layer and a signal layer) and are connected in parallel. However, the dual power areas with different sizes and shapes will have different impedances. As a result, the dual power areas separately consume different amounts of voltages thus providing different voltages to the component. Thus, more vias (basically for providing current paths) are defined in the dual power areas and extend through the power layer and the ground layer of the PCB to balance impedance of the power areas. The more vias defined in the dual power areas, the less the integrity of the power layer and the ground layer. Additionally, currents running through the vias generate heat. This leads to a shortened life of the PCB.

What is needed is a multi-layer PCB which is capable of providing a balanced power supply to a component requiring large working current and efficiently maintaining PCB integrity.

### SUMMARY

An exemplary multi-layer printed circuit board (PCB) is provided allowing balanced power supply to components requiring large working current. The PCB includes a plurality of layers disposed thereon. A first power area, and a second power area are separately arranged on different layers. The first power area and the second power area vertically aligned within the PCB with generally identical shapes cooperatively provide power to components requiring large working current.

Other advantages and novel features will become more apparent from the following detailed description when taken in conjunction with the accompanying drawings, in which:

### BRIEF DESCRIPTION OF THE DRAWINGS

FIG. 1 is a cross sectional view of a multi-layer printed circuit board (PCB) in accordance with a preferred embodiment of the present invention; and

FIG. 2 is an equivalent circuit diagram of a first power area, a second power area, and a plurality of vias of the FIG. 1.

### DETAILED DESCRIPTION OF THE EMBODIMENT

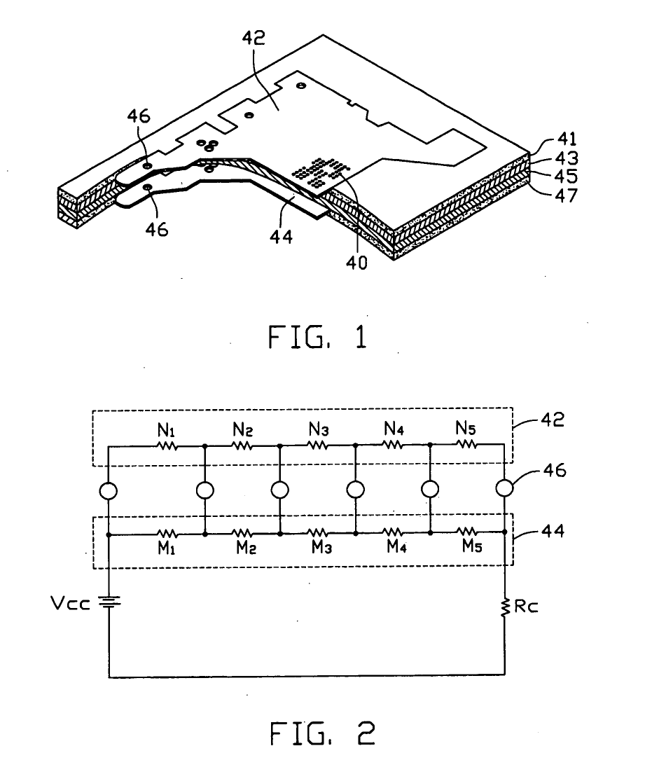

Referring to FIG. 1, a circuit assembly like a multi-layer printed circuit board (PCB) in accordance with a preferred embodiment of the present invention includes a first signal layer 41, a ground layer 43, a power layer 45, and a second signal layer 47 disposed sequentially one above the other. The first signal layer 41 includes a first power area 42. The first power area 42 includes a plurality of pads 40, for mounting a component requiring large working current thereon. The second signal layer 47 includes a second power area 44, cooperating with the first power area 42 to provide power to the component. A plurality of vias 46 is correspondingly defined in the first power area 42 and the second power area 44, electrically connecting the first power area 42 to the second power area 44. The vias 46 also extend through the ground layer 43 and the power layer 45 of the PCB. In the preferred embodiment, one of the pads 40 electronically connects with one of the vias 46 to provide power to the component. Alternatively, footprints of the component can be electronically connected with the vias 46.

Referring to FIG. 2, the first power area 42 and the second power area 44 are connected in parallel and connected to the power layer 45. A shape of the first power area 42 is same to that of the second power area 44 in a vertical alignment. A via layout on the first power area 42 is same to that on the second power area 44 in the vertical alignment. Distances between vias 46 of the first power area 42 are the same as distances between the corresponding vias 46 of the second power area 44. Regarding areas between vias 64 as segments, we show the segments in FIG. 2 and label them as segments N1˜N5 on the first power area 42 and segments M1 to M5 on the second power area 44. Each of the segments N1 to N5 and M1 to M5 has an impedance thereof, and vertical alignment and size matching of the power areas 42, 44 results in the impedances of the segments matching in the following manner: N1=M1, N2=M2, N3=M3, N4=M4, N5=M5. As a result of the impedances matching in such a way, paths of equal impedance thus power is drawn by the load in balanced manner from the two power areas 42, 44. Thus, only a minimum number of vias 46 (those actually needed for providing power to the component) are needed to be defined in the first power area 42 and the second power area 44 as current paths. As a result, integrity of the power layer 43 and the ground layer 45 is better maintained.

The multi-layer PCB may also include more power layers, and more signal layers. The first power area 42 and the second power area 44 can be separately arranged on any two different layers.

It is believed that the present embodiment and their advantages will be understood from the foregoing description, and it will be apparent that various changes may be made thereto without departing from the spirit and scope of the invention or sacrificing all of its material advantages, the example hereinbefore described merely being preferred or exemplary embodiment.

What is claimed is:

1. A multi-layer printed circuit board (PCB) comprising:
a first layer comprising a first power area formed therewith;
a second layer comprising a second power area formed therewith, the second power area being of a same shape and size as the first power area and in vertical alignment with the first power area; and
a minimum and equal number of vias are defined in the first power area and the second power area respectively.

2. The multi-layer PCB as claimed in claim 1, comprising at least two signal layers, and at least one power layer.

3. The multi-layer PCB as claimed in claim 2, wherein the first layer and the second layer are two separate signal layers.

4. The multi-layer PCB as claimed in claim 2, wherein the first layer and the second layer are two separate power layers.

5. The multi-layer PCB as claimed in claim 2, wherein the first layer is a signal layer, and the second layer is a power layer.

6. The multi-layer PCB as claimed in claim 1, wherein the vias in the first power area are aligned with and of a same size as vias in the second power area.

7. A multi-layer printed circuit board (PCB) comprising:
a first layer for mounting a component requiring a large working current and comprising a first power area;
a second layer parallel to the first layer;
a second power area formed on the second layer corresponding in size and shape and vertically aligned with the first power layer to cooperatively provide a balanced power supply to the component; and
current paths disposed between the first power area and the second power area.

8. The multi-layer PCB as claimed in claim 7, wherein the first power area and the second power area have an equal number of vias arranged in a same layout.

9. The multi-layer PCB as claimed in claim 7, comprising at least two signal layers, and at least one power layer.

10. The multi-layer PCB as claimed in claim 9, wherein the first layer is one of the at least two signal layers and the at least one power layer, and the second layer is one of the at least two signal layers and the at least one power layer.

11. The multi-layer PCB as claimed in claim 7, wherein the current paths are the vias defined through the first power area and the second power area.

12. A circuit assembly comprising:
a first layer defined in said circuit assembly for mounting at least one component thereon, said first layer comprising a first power area electrically connectable with said at least one component to power said at least one component for functioning thereof; and
a second layer defined in said circuit assembly, and spaced from and substantially parallel to said first layer, said second layer comprising a second power area substantially parallel to said first power layer and electrically connectable with said at least one component to power said at least one component for said functioning thereof, a projective area of said first power area onto said second layer entirely overlapping with said second power area of said second layer.

13. The circuit assembly as claimed in claim 12, further comprising a power layer and a ground layer defined in said circuit assembly between said first and second layers, said power layer spaced from and substantially parallel to said first power area and said second power area respectively.
